(19) United States
(12) Patent Application Publication
(10) Pub. No.: US 2026/0016683 A1
(43) Pub. Date: Jan. 15, 2026

(54) METHOD OF MANUFACTURING A LAYERED STRUCTURE FOR A MEMS APPARATUS AND MEMS APPARATUS WITH SUCH A LAYERED STRUCTURE

(71) Applicant: OQMENTED GMBH, Itzehoe (DE)

(72) Inventors: Frank SENGER, Hadenfeld (DE); Stephan MARAUSKA, Kaltenkirchen (DE); Ulrich HOFMANN, Itzehoe (DE)

(21) Appl. No.: 18/994,315

(22) PCT Filed: Jul. 12, 2023
(86) PCT No.: PCT/EP2023/069356

§ 371 Date: Jan. 14, 2025

(30) Foreign Application Priority Data
Jul. 14, 2022 (DE) 10 2022 117 678.9

(51) Int. Cl. G02B 26/08; B81B 3/00; B81C 1/00

(52) U.S. Cl. CPC G02B 26/0833; B81B 3/0045; B81C 1/0019; B81B 2201/042; B81B 2203/0163; B81B 2203/04; B81C 2201/0143

(57) ABSTRACT

The present disclosure relates to a method for manufacturing a layered structure for a MEMS apparatus, a layered structure which is a layered structure produced by the method, and a MEMS apparatus 200 which comprises such a layered structure. For the layered structure or the MEMS apparatus 200, an exemplary starting substrate is used in the manufacturing process, which forms the mechanically effective functional layer 10, wherein the mechanically effective functional layer 10 comprises a ferroelectric and/or piezoelectric material.

### DESCRIPTION

The present disclosure relates to a method of manufacturing a layered structure for a MEMS apparatus, a layered structure for a MEMS apparatus, and a MEMS apparatus comprising such a layered structure.

### BACKGROUND

A generic method for manufacturing a layered structure for a MEMS apparatus, in particular a piezoelectrically driven MEMS apparatus, as well as a generic layered structure for a MEMS apparatus and a generic MEMS apparatus comprising such a layered structure are known, for example, from US 2009/0185253 A1.

In the piezoelectrically driven MEMS apparatus known in the prior art, e.g. according to US 2009/0185253 A1, the mechanically effective functional layer (often referred to as the Device Layer) of the layered structure of the MEMS (micro-electro-mechanical system) is usually formed by a non-piezoelectric supporting layer (e.g. silicon), in which the moving or oscillating components, such as mirror-holding support elements and the holding spring structure, are formed, e.g. by so-called deep reactive ion etching (DRIE).

In the manufacturing process of the layered structure, piezoelectric material is usually applied to or deposited on the supporting functional layer. Therefore, a layered structure (also known as a MEMS wafer) is used in which piezoelectric material must be applied to the subsequent mechanically movable structure (e.g. silicon) of the functional layer by additional processing steps in the manufacturing process and then be removed again locally for structuring, e.g. by photolithographic masks and etching processes (e.g. with a subsequent etching of the surfaces unprotected by photoresist of the photolithographic mask).

All process steps are associated with costs and time. In addition, the growth of the ferroelectric/piezoelectric layers depends on the respective deposition process and also on the respective growth substrate, so that production-related fluctuations as well as integration-related limitations arise, and this also applies to the resulting piezoelectric coefficients of the driving piezoelectric layer.

In addition, the layer thicknesses of the ferro/piezoelectric layers applied by deposition are limited (typically to approx. 0.5 to 5 μm), which also limits the generation of forces or torques and the electrical drive voltage to be applied (breakdown field strength typically approx. 1-2 MV/cm).

In view of the disadvantages described above, it is an object of the present disclosure, based on the prior art described above, to provide an improved method for manufacturing a layered structure for a MEMS apparatus, in particular with cost and/or time savings and/or improved properties of the produced layered structure.

### SUMMARY

The present disclosure relates to a method of manufacturing a layered structure for a MEMS apparatus, a layered structure manufactured by the method, and a MEMS apparatus comprising the layered structure, in particular preferably a vacuum-packed MEMS mirror device.

In particular, a method for manufacturing a layered structure for a MEMS apparatus and a layered structure manufactured by the method according to the independent claims as well as a MEMS apparatus comprising the layered structure, in particular preferably a vacuum-packed MEMS mirror device, are proposed for solving the above-mentioned object. The dependent claims relate to some exemplary preferred embodiments.

According to a first aspect, in some embodiments, a method for manufacturing a layered structure for a MEMS apparatus, in particular a MEMS mirror device or a vacuum-packed MEMS mirror device, is proposed.

The method of manufacturing a layered structure for a MEMS apparatus exemplarily comprises providing a starting substrate which exemplarily comprises at least one functional layer (i.e. one or more functional layers) and/or structuring the at least one functional layer of the starting substrate.

The structuring of the at least one functional layer can preferably be performed to form one or more movable elements of the MEMS apparatus in the at least one functional layer and/or to form a spring structure, which preferably holds the one or more movable elements of the MEMS apparatus, in the at least one functional layer.

In some preferred embodiments, the at least one functional layer of the starting substrate may comprise ferroelectric and/or piezoelectric material.

In some embodiments, this is based on the idea that, for example, instead of a silicon substrate, a substrate comprising ferroelectric and/or piezoelectric material can be used as the starting substrate, and, in particular, the starting substrate comprising at least one functional layer which comprises ferroelectric and/or piezoelectric material. In particular, in some embodiments, the starting substrate may preferably comprise one or more ferroelectric and/or piezoelectric layers or one or more functional layers comprising ferroelectric and/or piezoelectric material.

In this way, numerous process steps can be saved in terms of costs and time, especially as deposition processes, e.g. of a piezoelectric layer, can be avoided.

In addition, the ferroelectric and/or piezoelectric substrate can form at least one functional layer in which the movable elements of the MEMS and/or the spring structure holding them can be formed.

The at least one functional layer can preferably form both the mechanically effective layer and simultaneously drive and/or detect the oscillating movements as an actuator and/or sensor.

In relation to a MEMS, “mechanically effective” here may mean in particular that the mechanically effective layer or the at least one mechanically effective functional layer (Device Layer) of the MEMS layered structure preferably forms the layer which, according to its structuring, is designed or formed to perform an oscillatory movement, in particular a one-dimensional or two-dimensional oscillatory movement, or in such a way that one or more structures or bodies formed in the mechanically effective layer or mechanically effective functional layer can perform an oscillation movement, in particular a one-dimensional or two-dimensional oscillation movement (e.g. about an oscillation/torsional axis or about two preferably transverse or in particular perpendicular oscillation/torsional axes, e.g. via springs of a spring structure, e.g. with bending springs, torsion springs and/or Meander springs, in particular e.g. for Lissajous scanning movements or preferably resonant Lissajous scanning movements).

Preferably, the holding structure and/or spring structure for the movable structures or bodies of the mechanically effective layer or mechanically effective functional layer can also be formed in this mechanically effective layer or mechanically effective functional layer.

In some embodiments, the holding structure and/or spring structure may comprise springs, in particular preferably bending springs, Meander springs and/or torsion springs, which may preferably be designed to hold one or more movable structures or bodies of the mechanically effective layer or mechanically effective functional layer, for example such that the movable structures or bodies can perform respective oscillating rotational movements about the corresponding axis (e.g. torsional oscillations) among one or more respective oscillating and/or torsional axes.

Furthermore, the formation of the mechanically effective layer or mechanically effective functional layer can preferably determine the resonant frequency or resonant frequencies of the MEMS, the deflection amplitudes and/or any dynamic deformations (e.g. in a holding structure and/or spring structure formed in the mechanically effective layer or mechanically effective functional layer or the formed structures or bodies, such as a mirror support element having a mirror plate).

Moreover, in some embodiments, the starting substrate or the one or more functional layers in the starting substrate can be provided as a ferro- and/or piezoelectric single crystal or polycrystal, and thus optimal ferro-/piezoelectric properties with optimal ferro/piezoelectric coefficients can be provided, which is not possible in conventional deposition processes due to process variations and growth conditions.

In some preferred embodiments, the starting substrate comprising the at least one functional layer may be made of ferroelectric and/or piezoelectric material.

In some preferred embodiments, one or more functional layers of the starting substrate may be made of ferroelectric and/or piezoelectric material.

Preferably, the starting substrate comprising the at least one functional layer may comprise one or more piezoelectric layers of ferro- and/or piezoelectric material, in particular one or more functional layers of ferro- and/or piezoelectric material.

In some preferred embodiments, the starting substrate comprising the at least one functional layer and/or the at least one functional layer of the starting substrate may comprise a single crystal of a ferro- and/or piezoelectric material and/or may comprise a single crystal of a ferro- and/or piezoelectric material.

In further preferred embodiments, the starting substrate comprising the at least one functional layer and/or at least one functional layer of the starting substrate may comprise a polycrystal of a ferro- and/or piezoelectric material and/or consist of a polycrystal of a ferro- and/or piezoelectric material.

In addition, in embodiments with multiple functional layers in the starting substrate, one or more functional layers of the starting substrate may comprise a single crystal of a ferro- and/or piezoelectric material and/or consist of a single crystal of a ferro- and/or piezoelectric material, wherein one or more further functional layers of the starting substrate may comprise a polycrystal of a ferro- and/or piezoelectric material and/or consist of a polycrystal of a ferro- and/or piezoelectric material.

In particular, the starting substrate is preferably not a silicon substrate and preferably the starting substrate does not comprise silicon or the starting substrate does not comprise a functional layer comprising silicon.

In some preferred embodiments, the ferro- and/or piezoelectric material may comprise aluminum nitride (AlN), aluminum scandium nitride (AlScN), lithium niobate (LiNbO3), lithium tantalate (LiTaO3), lead zirconate titanate (PZT), niobium-doped PZT (PZT-Nb), and/or quartz.

In some embodiments, the starting substrate comprising the at least one functional layer and/or at least one functional layer of the starting substrate may comprise and/or consist of an at least partially amorphous ferroelectric and/or piezoelectric material.

The at least partially amorphous (e.g. (partially) amorphous) ferroelectric and/or piezoelectric material may, for example, comprise PVDF (polyvinylidene fluoride (CF2—CH2)n) or consist of PVDF.

In some embodiments with multiple functional layers in the starting substrate, the starting substrate may be provided such that the starting substrate comprises, for example, at least one functional layer comprising or consisting of a ferro- and/or piezoelectric single crystal, at least one functional layer comprising or consisting of a ferro- and/or piezoelectric polycrystal, and/or at least one functional layer comprising or consisting of an at least partially amorphous ferro- and/or piezoelectric material.

In some preferred embodiments, a layer thickness of the at least one functional layer of the starting substrate comprising ferro- and/or piezoelectric material may be substantially greater than or equal to 50 μm, in particular substantially greater than or equal to 100 μm, and/or substantially less than or equal to 1 mm.

In particular preferred embodiments with several functional layers comprising ferroelectric and/or piezoelectric material, the layer thickness of each functional layer is preferably substantially greater than or equal to 50 μm, in particular preferably substantially greater than or equal to 100 μm, and/or substantially less than or equal to mm

In some preferred embodiments, the method may further comprise: applying and/or providing electrically conductive electrode layers on respective opposite sides (e.g. on front and back) of the at least one functional layer (e.g. already in the starting substrate between adjacent functional layers of the starting substrate, if the starting substrate comprises more than one ferro- and/or piezoelectric functional layer), and/or structuring the electrode layers to form patterned electrode surfaces on respective opposite sides (e.g. on front and back) of the at least one functional layer.

In some preferred embodiments, a mirror of the MEMS apparatus can be formed during the structuring of one of the electrode layers, in particular preferably during the structuring of an outer electrode layer or during the structuring of the upper or front electrode layer.

In further embodiments, a further mirror layer can also be applied to form a mirror of the MEMS apparatus. The mirror layer may comprise or consist of metal, e.g. aluminum. Alternatively or additionally, an electrode and/or mirror layer made of gold, platinum or silver can be used, depending on the area of application or wavelength range. For example, a mirror layer made of a more expensive metal, such as gold, platinum and/or silver, can be applied to an electrode layer made of a less expensive metal, e.g. aluminum.

In some preferred embodiments, when structuring the at least one functional layer of the starting substrate, a mirror support element can be formed in the at least one functional layer, wherein in particular preferably a mirror (e.g. the aforementioned mirror) can be arranged and/or formed on the mirror support element.

In some preferred embodiments, in particular when structuring the at least one functional layer, a spring structure which holds the mirror support element with mirror can be formed in the at least one functional layer, in particular in some embodiments preferably in such a way that the mirror support element with mirror is held such that it can oscillate, for example about one or two axes, in particular preferably oscillation and/or torsion axes, for example being held by bending springs, torsion springs and/or Meander springs.

In some embodiments, the spring structure may comprise springs, in particular preferably Meander springs, bending springs and/or torsion springs, which are preferably designed to hold the mirror support element in such a way that the mirror support element can perform an oscillating rotational movement about the respective oscillating and/or torsional axis (e.g. torsional oscillations).

In some embodiments with two axes, in particular two oscillating and/or torsional axes, the mirror support element with mirror and/or the spring structure is designed in particular preferably for a two-dimensional Lissajous scanning movement or preferably resonant two-dimensional Lissajous scanning movement of the mirror support element with mirror.

In some preferred embodiments, the conductive electrode layers for electrical contacting can be formed on opposite sides of the at least one functional layer.

In other preferred embodiments, one of the electrode layers (e.g. a second electrode layer) can be led to the side of the other (first) electrode layer by a through-hole plating in a region, in particular preferably in a central and/or lateral region, of the at least one functional layer, preferably in such a way that the conductive (first and second) electrode layers for electrical contacting can be formed on the same side of the at least one functional layer.

In particular, at least one second electrode layer of the conductive electrode layers can preferably be guided by a through-hole plating in a region of the at least one functional layer from a second side of the at least one functional layer to a first side of the at least one functional layer on which a first electrode layer of the conductive electrode layers is arranged.

Particularly preferably, at least the first electrode layer and the second electrode layer can be designed to provide electrical contacting of the first and second electrode layers on the same first side of the functional layer by the through-hole plating of the second electrode layer. For example, in some preferred embodiments, the (second) electrode layer arranged on a back side of the at least one functional layer can be guided by a through-hole plating in area region, in particular in a central or lateral region, of the at least one functional layer onto the front side on which the other (first) electrode layer is applied, preferably in such a way that the conductive (first and second) electrode layers can be designed for electrical contacting on the front side of the at least one functional layer, in that preferably the contacting of the (second) electrode layer applied to the rear side of the at least one functional layer can also be carried out on the front side.

In some preferred embodiments, the starting substrate may comprise a (e.g., exactly one) ferroelectric and/or piezoelectric functional layer.

In some preferred embodiments, the starting substrate may also comprise a plurality of ferroelectric and/or piezoelectric functional layers.

For example, the starting substrate can comprise two ferroelectric and/or piezoelectric functional layers, in particular preferably with a (second) electrode layer arranged in between. Corresponding (first) electrode layers can be arranged at the top and bottom (outer sides).

Furthermore, the starting substrate may comprise, for example, three or more ferro- and/or piezoelectric functional layers, wherein a respective electrode layer may preferably be arranged between adjacent ferro- and/or piezoelectric functional layers, in particular preferably in such a way that one, several or each ferro- and/or piezoelectric functional layer is arranged between two corresponding (first and second) electrode layers.

According to a second aspect, in some embodiments a layered structure is further proposed, which can preferably be produced in particular by the method according to at least one of the preceding exemplary aspects.

In some preferred embodiments, the layered structure may comprise: at least one structured functional layer in which preferably one or more movable elements of the MEMS apparatus and/or a spring structure holding the one or more movable elements of the MEMS apparatus may be formed.

The movable element(s) may, in particular in some embodiments, may comprise a mirror support element to which, exemplarily, a mirror plate and/or mirror layer may be applied, in particular for reflecting electromagnetic radiation, in particular preferably light in the visible and/or infrared range.

In some preferred embodiments, the at least one functional layer may comprise ferroelectric and/or piezoelectric material.

According to a third aspect, in some embodiments, a MEMS apparatus, in particular a MEMS mirror device or vacuum-packed MEMS mirror device, comprising a layered structure produced by the method according to at least one of the preceding exemplary aspects, is further proposed.

In operation, according to some embodiments, such MEMS apparatuses can be set up for periodic movements or oscillations in the frequency range from about 1 Hz to the kHz range, in embodiments preferably for frequencies substantially less than or equal to 200 kHz and in particular preferably for frequencies substantially less than or equal to 100 kHz.

This distinguishes such MEMS apparatuses from so-called oscillating quartz devices, which are set up for the frequency range in the MHz range.

Further aspects and examples of embodiments as well as advantages and more specific embodiments of the aspects and features described above can also be found in the following descriptions and explanations of the attached drawings, which are not to be understood as limiting in any way.

### BRIEF DESCRIPTION OF THE DRAWINGS

FIG. 1A shows an exemplary sectional view of a layered structure for a MEMS apparatus according to a background example,

FIG. 1B shows an exemplary sectional view of a MEMS apparatus comprising the layered structure shown in FIG. 1A,

FIG. 2 shows exemplary sectional views of the layer structure during a manufacturing process according to an exemplary manufacturing sequence of an exemplary embodiment,

FIG. 3 shows an exemplary functional schematic sectional view of a layered structure manufactured according to FIG. 2,

FIG. 4 shows an exemplary functional schematic sectional view of a layered structure according to a further exemplary embodiment,

FIG. 5 shows an exemplary schematic sectional view of a MEMS apparatus comprising the layered structure according to FIG. 3,

FIG. 6 shows an exemplary schematic sectional view of a MEMS apparatus comprising the layered structure according to FIG. 4,

FIG. 7 shows exemplary sectional views of the layer structure during a manufacturing process according to an exemplary manufacturing sequence of a further exemplary embodiment,

FIG. 8 shows an exemplary schematic sectional view of a MEMS apparatus comprising the layered structure shown in FIG. 7,

FIG. 9 shows exemplary sectional views of the layer structure during a manufacturing process according to an exemplary manufacturing sequence of a further exemplary embodiment, and

FIG. 10 shows an exemplary schematic sectional view of a MEMS apparatus comprising the layered structure shown in FIG. 9.

### DETAILED DESCRIPTION OF THE DRAWINGS AND PREFERRED EMBODIMENTS

In the following, examples or embodiments of the present disclosure are described in detail with reference to the accompanying drawings. Identical or similar elements in the drawings may be designated with the same reference signs, but sometimes also with different reference signs.

However, it should be emphasized that the objects of the present disclosure are in no way limited or restricted to the embodiments described below and their features, but further include modifications of the embodiments, in particular those encompassed by modifications of the features of the described examples or by combination of one or more of the features of the described examples within the scope of protection of the independent claims.

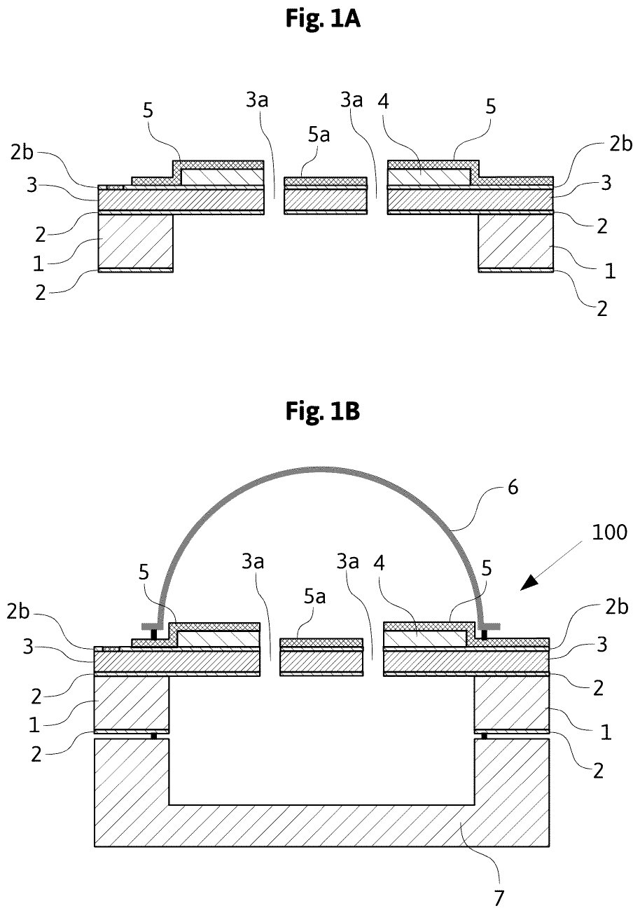

First of all, a background example is described below with reference to FIGS. 1A and 1B, which is intended to facilitate understanding of the embodiments and advantages described below. However, the layered structure on which FIGS. 1A and 1B are based is not actually already publicly known prior art.

A generic layer structure from the prior art and a corresponding manufacturing process can be found, for example, in US 2009/0185253 A1.

Even if the following description with reference to FIGS. 1A and 1B refers to a background example, any described technical details and/or features of the method, the manufacturing sequence, the layer structure and in particular to individual steps and/or layers of the layer structure may also relate to corresponding details and/or features of the exemplary embodiments described below, unless a difference is explicitly pointed out.

FIG. 1A shows an exemplary sectional view of a layered structure for a MEMS apparatus according to a background example. FIG. 1B shows an exemplary sectional view of a MEMS apparatus comprising the layered structure according to the background example in FIG. 1A.

The layer structure comprises, for example, a substrate layer 1, a functional layer 3, which is applied (for example with an intermediate passivation layer 2) to the substrate layer 1, a piezoelectric layer 4 (e.g. with bottom electrode or counter electrode of the top electrode), which is applied (for example with an intermediate passivation layer 2b) to the functional layer 3, and an electrode layer 5, which is applied to the piezoelectric layer 4 or to regions of the functional layer 3.

The electrode layer 5 exemplarily forms the top electrode of the piezoelectric layer 4 and exemplarily forms a mirror 5a in one area (e.g. in the middle area), which is arranged on the functional layer 3.

In the following, explanations of the possible manufacturing process for a layer structure according to FIG. 1A are given as an example.

In the exemplary manufacturing process, respective passivation layers 2 and/or 2b (exemplary intermediate layers) can be applied to the top and bottom (or front and back) of the substrate layer 1. Furthermore, the functional layer 3 (often referred to as a device layer) can be applied the substrate layer 1 on the top side of the substrate layer 1 with an exemplary passivation layer 2 (intermediate layer) in between.

The substrate layer 1 can, for example, be made of silicon or comprise silicon. In suitable embodiments, the substrate layer 1 can be provided, for example, as an SCS wafer (SCS, “single-crystal-silicon”, for example, as a crystalline bulk silicon substrate).

Furthermore, the substrate layer can also be provided by an SOI wafer (SOI, “silicon-on-insulator”), which can already comprise the substrate layer 1 and, for example, also the functional layer 3 and/or the intermediate layer(s) 2.

Exemplary SOI wafers may comprise a handling wafer, which may comprise e.g. crystalline bulk silicon substrate, exemplarily followed by an intermediate layer (typically a silicon oxide, e.g. 100-2000 nm).

In other examples, the intermediate layers (e.g. the intermediate layers 2 and/or 2b) can also consist of other (e.g. dielectric) layers, such as silicon nitride, silicon oxynitride or aluminum oxide. In particular, different intermediate layers can consist of different materials.

The functional layer 3 (e.g. with layer thicknesses of e.g. 5-300 μm) later forms the mechanically effective layer. The functional layer 3 can, for example, be made of silicon or comprise silicon and can, for example, also consist of a pure crystalline substrate (e.g. SCS, “single-crystal-silicon”) or be applied using epitaxial deposition processes, e.g. also in polycrystalline form.

Furthermore, a piezoelectric layer 4 can be applied to the functional layer 3, for example with a further interposed passivation layer 2b. Here, an electrically conductive layer can preferably be provided on the underside of the piezoelectric layer 4, which can be used as the bottom electrode of the piezoelectric layer 4.

The piezoelectric layer 4 may preferably comprise piezoelectric material or be formed from piezoelectric material which preferably has high piezoelectric and/or ferroelectric constants.

For example, the piezoelectric layer 4 may comprise aluminum nitride (AIN), aluminum scandium nitride (AlScN), lead zirconate titanate (PZT) or niobium-doped PZT (PZT-Nb). The piezoelectric layer 4 may also comprise semi-crystalline polymer materials such as PVDF (polyvinylidene fluoride (CF2—CH2)n).

Furthermore, the piezoelectric layer 4, for example, which is applied to or above the functional layer 3, can be structured in the next step or also in later process steps, in particular preferably by a wet and/or dry etching process.

The remaining areas of the piezoelectric layer 4 preferably define the piezoelectric elements and/or drive and/or sensing elements (e.g. actuator and/or sensor surfaces) in the later MEMS structure for generating, driving, controlling and/or sensing the movements or vibrations of the movably held components or elements of the MEMS.

In a further step, for example, an electrode layer 5 can be applied to the piezoelectric layer 4 (which can optionally already be structured beforehand)

In a further exemplary step, the electrode layer 5, which is applied to or above the piezoelectric layer 4, can be structured. In the exemplary step of structuring the electrode layer 5, for example, the desired structure of the top electrode (top electrode) for the upper electrical contacting of the piezoelectric layer 4 can be formed.

Furthermore, in the step of structuring the electrode layer 5, a mirror 5a (e.g. a mirror layer with a reflective surface) can be formed in an area, e.g. in the center of the layer structure, using the material of the electrode layer 5 as an example.

In such examples, the electrode layer may comprise metal, in particular aluminum, so that the surface of the electrode layer 5 already has a reflective surface and is suitable for forming the mirror 5a. For example, a top electrode layer deposited over the entire surface, e.g. made of metal, in particular aluminum, can be structured using wet or dry chemical photolithographic steps, e.g. using spray-coat lithography, using a lift-off process in which the lithography takes place before the metal deposition, or, for example, using positive photoresist lithography.

In a further exemplary step, the functional layer 3 can be structured in areas 3a. In particular, the mechanically effective structures of the MEMS apparatus can be formed in the functional layer. This includes, for example, forming or exposing the mirror support element which can be formed, for example, from central areas of the functional layer 3 (here, for example, the area of the functional layer 3 under the mirror layer 5a) as well as any retaining webs that can be formed from the functional layer 3 and that can act, for example, as a retaining spring structure and that hold the mirror support element so that it can oscillate, for example, about one, two or more oscillation or torsion axes (e.g. about one oscillation/torsion axis or about two oscillation/torsion axes, preferably transverse or in particular perpendicular to each other, e.g. via springs of the spring structure, e.g. with bending springs, torsion springs and/or Meander springs, in particular e.g. for Lissajous scanning movements or preferably resonant Lissajous scanning movements).

In some embodiments, the spring structure may comprise springs, in particular preferably bending springs, Meander springs and/or torsion springs, which are preferably designed to hold the mirror support element in such a way that the mirror support element can perform an oscillating rotational movement about the respective oscillating and/or torsional axis (e.g. torsional oscillations).

In the methods commonly used in the prior art, so-called deep reactive ion etching (DRIE) is usually used to structure the functional layer 3 in order to form the deep trenches in the functional layer 3 (e.g. areas 3a). For example, deep reactive ion etching can be carried out to structure the functional layer 3 using a photolithography mask.

In a further exemplary step, the layer structure can be opened at the backside in order to expose the functional layer 3 on the side (backside) opposite the piezoelectric layer 4.

In a further exemplary step, the manufactured layered structure can be provided in a vacuum-packed MEMS apparatus 100 according to FIG. 1B.

For example, the layered structure can be hermetically sealed from above with a translucent cover element 6 (e.g. a translucent dome element or a glass dome) and/or from below with a base element or base body element 7 under a vacuum atmosphere (e.g. vacuum encapsulation). In some further embodiments, differently shaped cover elements or 3D-shaped cover elements are also possible to be provided (e.g. angular or planar, e.g. also an inclined window or a planar window). The material of the cover elements is preferably translucent, e.g. made of glass or other optically transparent materials (e.g. approx. 400-2500 nm), such as borosilicate glass (e.g. Borofloat® BF33 by SCHOTT).

Thus, a vacuum-packed (or vacuum-encapsulated) MEMS mirror device 100 (e.g., a MEMS mirror scanner) comprising the fabricated layered structure can be provided with piezoelectrically driven, deflectable or steerable mirror 5a as shown in FIG. 1B.

Various exemplary embodiments are described below. Any details or exemplary features from the above examples, in particular relating to individual process steps and materials, may also apply analogously to the embodiments below, unless differences are explicitly pointed out. Furthermore, descriptions of details or exemplary features from the following embodiment examples, in particular of individual process steps and materials, can also apply analogously to other embodiment examples, unless differences are explicitly pointed out.

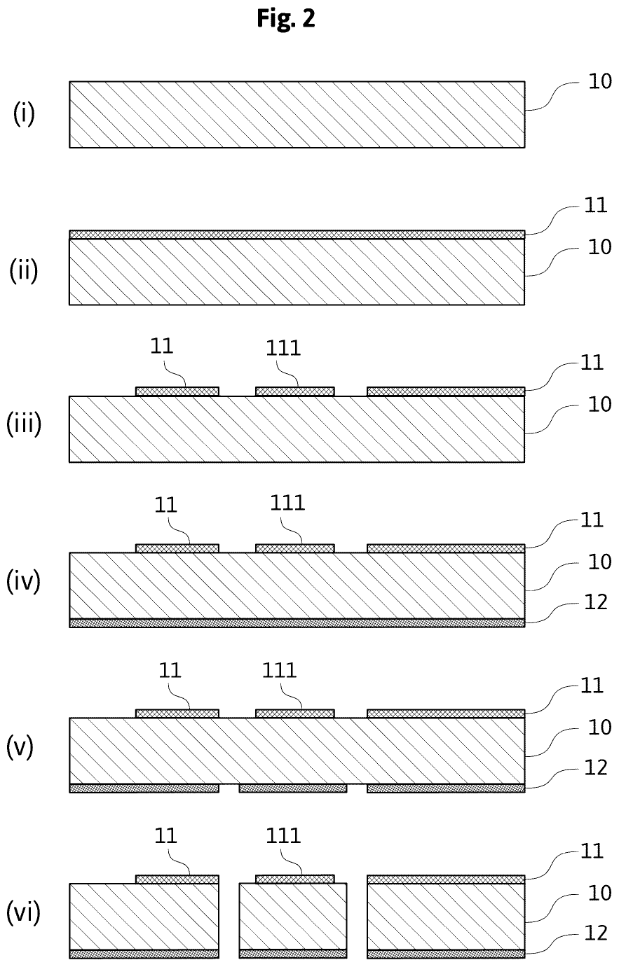

FIG. 2 shows exemplary sectional views of the layer structure during a manufacturing process according to an exemplary manufacturing sequence of an embodiment example. In further possible embodiments, the sequence of steps may also be different, steps may be omitted and/or additional steps may be added.

A basic idea of some embodiments is that the at least one functional layer, which later forms the mechanically effective layer of the MEMS apparatus, is formed from piezoelectric and/or ferroelectric material, in contrast to the above background example.

Thus, exemplarily, the mechanically acting functional layer (i.e. in particular the layer or layers that form the moving elements or oscillating elements of the MEMS) is already ferroelectric and/or piezoelectric, whereby this ferroelectric and/or piezoelectric functional layer also drives the amplitude and/or frequency of the movements or vibrations in the MEMS, functioning as an actuator, and/or detects them, functioning as a sensor. This means that no further piezoelectric layer needs to be deposited on the functional layer.

In contrast to the above background example and in particular also in contrast to the prior art, this thus advantageously enables the saving of many manufacturing steps, including various deposition steps, such as the deposition of the functional layer 3 and the deposition of the piezoelectric layer 4, and also the backside opening or exposure of the functional layer 3 (e.g. by backside opening of the substrate layer 1 in the above background example). As a result, considerable cost and time savings can be achieved in the manufacturing process.

Moreover, in some embodiments, the starting substrate comprising the functional layer 3 may be provided as a single or multilayer piezoelectric single crystal or polycrystal in some embodiments. This enables improved or optimized piezoelectric properties with optimized piezoelectric coefficients, in particular compared to previously known methods in which the piezoelectric layer is deposited on the starting substrate in the process.

Here, a substrate layer 10 of a ferroelectric/piezoelectric material can be provided directly (e.g. instead of a layer structure with substrate layer 1 and functional layer 3), hereinafter referred to as piezoelectric functional layer 10; see e.g. FIG. 2 (i).

In some preferred embodiments, the piezoelectric functional layer 10 can be provided as a substrate of a ferro/piezoelectric single crystal or polycrystal. However, the piezoelectric functional layer 10 may also be at least partially amorphous.

In some preferred embodiments, the layer thickness of the piezoelectric functional layer 10 may be substantially greater than or equal to 50 μm, preferably substantially greater than or equal to 100 μm, exemplarily even substantially greater than or equal to 200 μm. In embodiments, the piezoelectric functional layer 10 can be provided with a layer thickness of substantially greater than or equal to 100 μm and/or substantially less than or equal to 1 mm.

In some preferred embodiments, the piezoelectric functional layer 10 may comprise ferroelectric and/or piezoelectric material or may be formed of ferroelectric and/or piezoelectric material that preferably has high piezoelectric and/or ferroelectric constants.

For example, the piezoelectric functional layer 10 may comprise aluminum nitride (AlN), aluminum scandium nitride (AlScN), lithium niobate (LiNbO3), lithium tantalate (LiTaO3), lead zirconate titanate (PZT), niobium-doped PZT (PZT-Nb) and/or quartz or consist of one of the aforementioned materials.

In a further step, an electrically conductive layer, hereinafter referred to as the first electrode layer 11, can be applied to or deposited on one side of the piezoelectric functional layer 10 provided; see, for example, FIG. 2 (ii).

In a further step, the first electrode layer 11 can be structured; see e.g. FIG. 2 (iii). Here, in embodiments, the upper (front) electrode surfaces can be formed for the deflection of the piezoelectric crystal or the piezoelectric functional layer 10. In the exemplary step of structuring the first electrode layer 11, the desired structure of the upper electrode (top electrode) for the upper (front) electrical contacting of the piezoelectric functional layer 10 can thus be formed.

In some embodiments, e.g. in the manufacture of a layered structure for a MEMS mirror device, one or more mirrors or mirror plates, such as mirror 111 in FIG. 2 (iii), can also be shaped in this step. For example, in the step of structuring the first electrode layer 11, a mirror 111 (e.g. a mirror layer with a surface reflecting electromagnetic radiation) can be formed in areas, e.g. in the center, of the layer structure using the material of the electrode layer 11.

In some embodiments, the first electrode layer 11 may comprise, for example, metal, in particular aluminum, so that the surface of the first electrode layer 11 may preferably already have a reflective surface and/or be suitable for forming the mirror 111.

For example, a top electrode layer deposited over the entire surface, e.g. made of metal, in particular aluminum, can be structured via photolithographic steps using wet or dry chemistry, e.g. by spray-coat lithography or alternatively via a lift-off process in which the lithography takes place before the metal deposition. In some embodiments, the electrode layer can also be applied by shadow mask deposition.

In further examples, it is possible to provide a non-reflective electrode layer (or also, for example, a less reflective electrode layer, e.g. reflection substantially less than or equal to 60% in the relevant wavelength range) and/or a non-metallic electrode layer (e.g. doped polycrystalline silicon), whereby a further, for example metallic, mirror layer (e.g. as a thin-layer metal film) can then be applied in a further process step, e.g. in the center, to form a mirror.

In some preferred embodiments, the material of the (front-side) metallic electrode layer 11 or mirror layer 111 can be selected depending on the desired application for the respective wavelength range, in particular with very good reflection behavior in the wavelength range of the desired application (e.g. substantially greater than or equal to 85% in the relevant wavelength range), for example aluminum or silver for visible light (e.g. substantially at wavelengths of 400-700 nm) or gold for infrared light or infrared radiation (e.g. essentially at wavelengths of 850-2000 nm).

In a further step, a further electrically conductive layer, hereinafter referred to as the second electrode layer 12 (or counter electrode), can be applied to or deposited on one side of the piezoelectric functional layer 10 which is opposite the first electrode layer 11 (i.e. e.g. on the rear side); see e.g. FIG. 2 (iv).

In some embodiments, the second electrode layer 12 may comprise, for example, metal, in particular aluminum.

For example, a bottom electrode layer deposited over the entire surface, e.g. made of metal, in particular aluminum, can be structured by photolithographic steps using wet or dry chemistry, e.g. by spray-coat lithography or alternatively using a lift-off process in which the lithography takes place before the metal deposition. In some embodiments, the electrode layer can also be applied by shadow mask deposition.

In further examples, it is possible to provide a non-reflective or non-metallic electrode layer (e.g. doped polycrystalline silicon).

In a further step, the second electrode layer 12 can be structured; see e.g. FIG. 2 (v). Here, in embodiment examples, the lower electrode surfaces for the deflection of the piezoelectric crystal or the piezoelectric functional layer 10 can be formed. In the exemplary step of structuring the second electrode layer 12, the desired structure of the lower electrode (e.g. rear bottom electrode) for the lower electrical contacting of the piezoelectric functional layer 10 can thus be formed. The structured electrode layer 12 can thus be used as a counter electrode or counter electrode surface(s) to the electrodes of the first electrode layer 11, e.g. for the negative potential.

In a further step, the piezoelectric functional layer 3 can be structured; see e.g. FIG. 2 (vi). In particular, the mechanically effective structures of the MEMS apparatus can be formed in the functional layer. This includes, for example, forming or exposing the mirror support element formed from (e.g. central) areas of the functional layer 10 (here, for example, the area of the functional layer 10 under the mirror layer 111) and the retaining webs, which can be formed from the functional layer 10 and can act, for example, as a holding spring structure, and which can hold the mirror support element so that it can oscillate about one, two or more oscillation or torsion axes, for example (e.g. about one oscillation/torsion axis or about two oscillation/torsion axes which are preferably transverse or in particular perpendicular to each other, e.g. via springs of the spring structure, e.g. with bending springs, torsion springs and/or Meander springs, in particular e.g. for Lissajous scanning movements or preferably resonant Lissajous scanning movements).

In some embodiments, the spring structure may comprise springs, in particular preferably bending springs, Meander springs and/or torsion springs, which are preferably designed to hold the mirror support element in such a way that the mirror support element can perform an oscillating rotational movement about the respective oscillating and/or torsional axis (e.g. torsional oscillations).

The structuring of the functional layer 10 can be carried out using photolithographic steps using wet or dry chemistry. In this case, the structuring of the functional layer 10 can be carried out together with the structuring of the second electrode layer 12 or at least with the same mask. In further embodiments, the structuring of the functional layer 10 can also be carried out independently of the structuring of the second electrode layer 12 and/or with a further photolithographic mask (e.g. with a subsequent etching of the surfaces unprotected by photoresist of the photolithographic mask).

Other structuring processes are also possible in further embodiments, e.g. by laser ablation or also by the so-called LIDE process (Laser Induced Deep Etching), in which, for example, the crystal is chemically and physically altered in areas in which the crystal has been exposed or irradiated in such a way that significantly higher etching rates occur in those areas (e.g. in wet chemistry) compared to other areas that have not been exposed or irradiated.

In the above embodiments, the electrode layers 11 and 12 may be exemplarily applied or deposited on respective sides (e.g. front and back) of the ferroelectric and/or piezoelectric functional layer 10.

In further embodiments, it is expediently possible to already provide a starting substrate which comprises the ferroelectric and/or piezoelectric functional layer 10 and in which, for example, one or both of the electrode layers 11 and 12 have already been applied, for example bonded to the functional layer 10, or as a laminated layer composite which already comprises the functional layer 10 as well as the first electrode layer 11 and/or the second electrode layer 12.

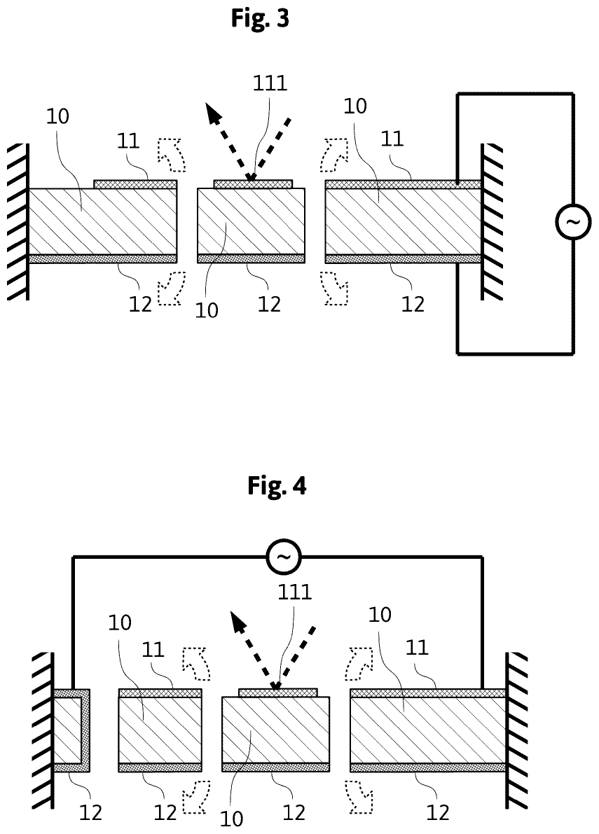

FIG. 3 shows an exemplary schematic functional sectional view of a layered structure, manufactured for example according to FIG. 2, in an exemplary electrical driving circuit.

On the right-hand side in FIG. 3, it is shown schematically as an example that at least one AC voltage can preferably be applied between at least one electrode of the first electrode layer 11 and at least one electrode of the second electrode layer 12, for example to control (and/or detect) the voltage generation or the voltage drop across the piezoelectric substrate or the piezoelectric functional layer 10. In some further embodiments, several AC voltage sources can also be used for different actuator surfaces (e.g. with different frequencies for oscillations in transverse or perpendicular torsion or oscillation axes, e.g. via springs of a spring structure, e.g. with bending springs, torsion springs and/or Meander springs, e.g. for 2D Lissajous scanning movements or preferably resonant 2D Lissajous scanning movements of the mirror 111).

The thin dashed arrows in FIG. 3 schematically illustrate, exemplarily, the controllable or excitable and/or detectable deflection of the piezoelectric functional layer 10, whereby an oscillation or oscillating movement of the mirror support element of the piezoelectric functional layer 10, which is arranged under the mirror 111, can be driven and/or detected. The thick dashed arrow in FIG. 3 schematically illustrates the reflection of a light beam on the (oscillating or moving) mirror 111 as an example.

FIG. 4 shows an exemplary schematic functional sectional view of a layered structure according to a further exemplary embodiment in a further exemplary electrical drive circuit.

In contrast to the example in FIG. 3, in further embodiments, as shown for example in FIG. 4, the second (rear) electrode layer 12 can be plated through, in which at least in an exemplary lateral (or central) region of the functional layer 10, the second electrode layer 12 (exemplary on the left-hand side in FIG. 4) or at least a section of the second electrode layer 12 (or an electrode section electrically connected to the second electrode layer 12) is led to the side (front side) of the functional layer 10 on which the first electrode layer 11 is arranged. Such a through-hole plating can, for example, be made through or along one or more structured areas of the functional layer 10 (e.g. on one or more side walls of one or more structured areas or structured trenches of the functional layer 10).

Conveniently, the electrical contacting of the electrodes of the first and second electrode layers 11 and 12 can be provided on the same side (front side) of the functional layer 10. The complexity of the structure of the MEMS and in particular the contacts and connection technology can thus be simplified. For example, simple wire bonds can be placed on the front side and/or simple solder balls can be provided on the back side.

On the upper side (front side), it is shown schematically exemplarily that at least one alternating voltage can preferably be applied between at least one electrode of the first electrode layer 11 and at least one electrode of the second electrode layer 12 with exemplary contacting on the upper side (front side), for example in order to control (and/or detect) the voltage generation or the voltage drop across the piezoelectric substrate or the piezoelectric functional layer 10. In some embodiments, several AC voltage sources can also preferably be used here for different actuator surfaces (e.g. with different frequencies for oscillations in transverse or perpendicular torsion or oscillation axes, e.g. via springs of a spring structure, e.g. with bending springs, torsion springs and/or Meander springs, e.g. for 2D Lissajous scanning movements or preferably resonant 2D Lissajous scanning movements of the mirror 111).

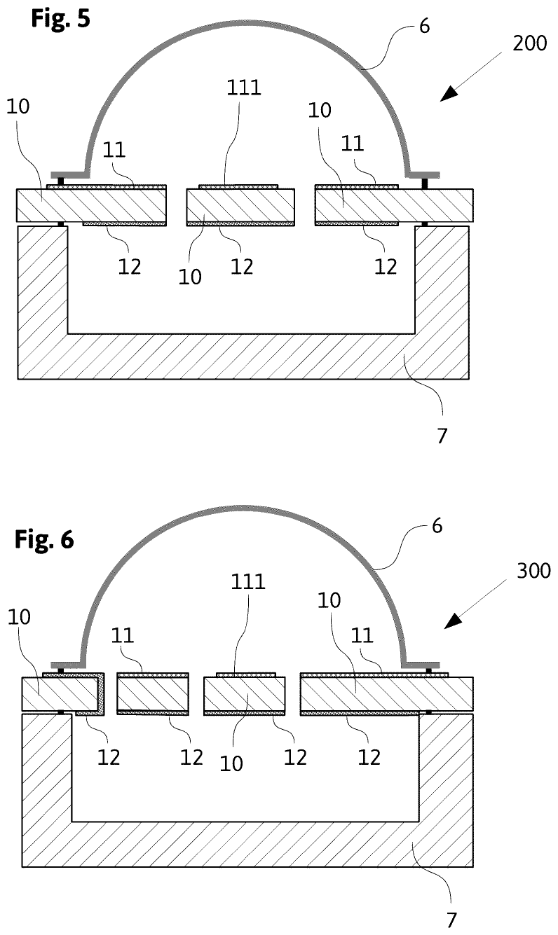

FIG. 5 shows an exemplary schematic sectional view of a MEMS apparatus 200, which exemplarily comprises the layered structure according to FIG. 3. In this example, the layered structure can be hermetically sealed from above with a translucent cover element 6 (e.g. a translucent dome element or a glass dome) and/or from below with a base element or base body element 7 under a vacuum atmosphere (e.g. vacuum encapsulation).

FIG. 6 shows an exemplary schematic sectional view of a MEMS apparatus 300, which exemplarily comprises the layered structure according to FIG. 4. In this example, the layered structure can be hermetically sealed from above with a translucent cover element 6 (e.g. a translucent dome element or a glass dome) and/or from below with a base element or base body element 7 under a vacuum atmosphere (e.g. vacuum encapsulation).

In further embodiments, differently shaped cover elements or 3D-shaped cover elements are also possible (e.g. angular or planar, e.g. also an inclined window or a planar window). The material of the cover elements is preferably translucent, e.g. glass or other optically transparent materials (e.g. approx. 400-2500 nm), such as borosilicate glass (e.g. Borofloat® BF33 from SCHOTT).

Consequently, an exemplary vacuum-packed (or vacuum-encapsulated) MEMS mirror device 200 or 300 (e.g., a MEMS mirror scanner) comprising the respective fabricated layered structure can be provided with piezoelectrically deflectable or controllable mirrors 111 that can be used for exemplary 1D and/or 2D scanning motions of the mirror 111 (e.g., 2D scanning motions for Lissajous scans or preferably resonant 2D scanning motions for Lissajous scans, i.e., e.g., a bi-resonant mirror 111 with resonant 2D scanning motions for Lissajous scans, e.g. via springs of a spring structure, e.g. with bending springs, torsion springs and/or Meander springs).

In FIGS. 5 and 6, an exemplary fixation of the layered structure (in particular in order to hold the spring structures in the outer region, which hold the mirror support element or the mirror 111), which is only shown schematically as an example in FIGS. 3 and 4, is provided as an example by the attachment to the exemplary base element or base body element 7.

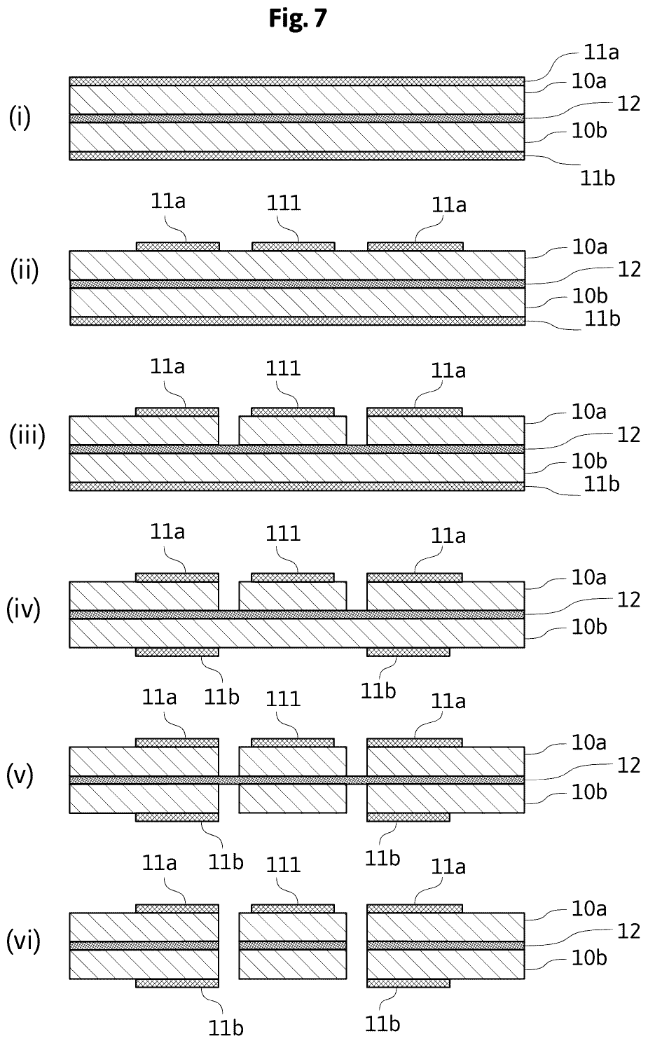

FIG. 7 shows exemplary sectional views of the layer structure during a manufacturing process according to an exemplary manufacturing sequence of a further exemplary embodiment. In other possible processes, the order of the steps can also be different, steps can be omitted and/or additional steps can be added.

Whereas in the embodiments described above, the respective starting substrate is exemplarily provided with a ferroelectric or piezoelectric functional layer 10, in contrast to the above embodiments, an exemplary starting substrate according to FIG. 7(i) is now provided, which exemplarily comprises two ferroelectric or piezoelectric functional layers 10a and 10b. These two ferroelectric or piezoelectric functional layers 10a and 10b (or the ferroelectric or piezoelectric layers 10a and 10b, which form the functional layer) can comprise the same ferroelectric or piezoelectric material and/or also different ferroelectric or piezoelectric materials.

As an example, the starting substrate according to FIG. 7(i) can also already be provided in such a way that a (second) electrode layer 12, for example a metallic electrode layer, is arranged between the two ferroelectric or piezoelectric functional layers 10a and 10b. Exemplarily, the starting substrate according to FIG. 7(i) can be provided in some embodiments in such a way that the two ferroelectric or piezoelectric functional layers 10a and 10b and the exemplary (second) electrode layer 12 located between them are bonded or laminated.

On opposite outer sides (e.g. front and rear sides) of the starting substrate according to FIG. 7(i), respective (first) electrode layers 11a and 11b are arranged exemplarily. These (first) electrode layers 11a and 11b can, for example, either can be applied to the starting substrate (e.g. by deposition processes) or can also, for example, already be provided in the starting substrate (e.g. bonded or laminated to the respective functional layer 10a/10b).

In the exemplary manufacturing process according to FIG. 7, the (first) electrode layer 11a lying on top (front side) can also be structured (e.g. analogous to electrode layer 11 in FIG. 2(iii)); see e.g. FIG. 7(ii).

For example, in the step of structuring the (first) electrode layer 11a, e.g. in the center of the layer structure, a mirror 111 (e.g. mirror layer with reflective surface) can be formed by the material of the electrode layer 11a.

In some embodiments, the (first) electrode layer 11a may comprise, for example, metal, in particular aluminum, so that the surface of the (first) electrode layer 11a already comprises, for example, a reflective surface and/or is suitable for forming the mirror 111.

In some preferred embodiments, the material of the metallic (first) electrode layer 11a or mirror layer 111 can be selected depending on the desired application for the respective wavelength range, in particular with very good reflection behavior in the wavelength range of the desired application, for example aluminum or silver for visible light (e.g. essentially at wavelengths of 400-700 nm) or gold for infrared light or infrared radiation (e.g. essentially at wavelengths of 850-2000 nm).

In the exemplary manufacturing process according to FIG. 7, the first ferroelectric or piezoelectric functional layer 10a can also be structured analogously to FIG. 2 (vi); see, for example, FIG. 7(iii).

The (front-side) structuring of the ferroelectric or piezoelectric functional layer 10a can be carried out via photolithographic steps using wet or dry chemistry. In some embodiments, the structuring of the ferroelectric or piezoelectric functional layer 10a can be carried out together with the structuring of the electrode layer 12 or at least with the same mask.

In further embodiments, the structuring of the ferroelectric or piezoelectric functional layer 10a can be carried out independently of the structuring of the electrode layers 11a and/or 12 and/or with a further photolithographic mask (e.g. with a downstream etching of the surfaces unprotected by photoresist of the photolithographic mask). Other structuring processes are also possible in further embodiments, e.g. structural laser ablation or also by the so-called LIDE process (Laser Induced Deep Etching).

In the exemplary manufacturing process according to FIG. 7, the (first) electrode layer 11b lying at the bottom (back) can furthermore be structured; see, for example, FIG. 7(iv). In some embodiments, the (first) electrode layer 11b may comprise, for example, metal, in particular aluminum.

In the exemplary manufacturing process according to FIG. 7, the second ferroelectric or piezoelectric functional layer 10b can also be structured (analogous to the functional layer 10a); see, for example, FIG. 7(v).

The (back side) structuring of the ferroelectric or piezoelectric functional layer 10b can be carried out using wet or dry chemical photolithographic steps. Here, the structuring of the ferroelectric or piezoelectric functional layer 10b can be carried out together with the structuring of the electrode layer 12 or at least with the same mask.

In further embodiments, the structuring of the ferroelectric or piezoelectric functional layer 10b can be carried out independently of the structuring of the electrode layers 11b and/or 12 and/or with a further photolithographic mask (e.g. with a subsequent etching of the surfaces unprotected by photoresist of the photolithographic mask). Other structuring methods are also possible in further embodiments, e.g. by laser ablation or also by the so-called LIDE method (Laser Induced Deep Etching).

In the exemplary manufacturing process according to FIG. 7, the (second) electrode layer 12 (counter electrode) can furthermore be structured; see, for example, FIG. 7(vi). In some embodiments, the (second) electrode layer 12 may comprise, for example, metal, in particular aluminum.

Here, the mechanically effective structures of the MEMS apparatus can be formed in the ferroelectric or piezoelectric functional layers 10a and 10b by structuring the ferroelectric or piezoelectric functional layer(s), in particular by structuring the ferroelectric or piezoelectric functional layers 10a and 10b (and structuring the electrode layer 12).

This includes, for example, forming or exposing the mirror support element formed from (e.g. central) regions of the ferroelectric or piezoelectric functional layers 10a and 10b (here, for example, the region under the mirror layer 111) and the retaining webs, which can be formed from the functional layers 10a and 10b and can act, for example, as a holding spring structure, and which can, for example, hold the mirror support element so that it can oscillate about one, two or more oscillation or torsion axes (e.g. about an oscillation/torsion axis or about two oscillation/torsion axes that are preferably transverse or, in particular, perpendicular to one another, e.g. via springs of the spring structure, e.g. with bending springs, torsion springs and/or Meander springs, in particular e.g. for Lissajous scanning movements or preferably resonant Lissajous scanning movements).

In some embodiments, the spring structure may comprise springs, in particular preferably bending springs, Meander springs and/or torsion springs, which are preferably designed to hold the mirror support element in such a way that the mirror support element can perform an oscillating rotational movement about the respective oscillating and/or torsional axis (e.g. torsional oscillations).

In some embodiment examples with two or more ferroelectric or piezoelectric functional layers, even greater deflections and/or even greater acting forces or torques can be advantageously enabled, if required, compared to previous embodiment examples with one ferroelectric or piezoelectric functional layer, if this is necessary or desired depending on the application. In further embodiments with two or more ferroelectric or piezoelectric functional layers, the drive voltage can be advantageously reduced with constant deflection angles compared to the previous embodiments with one ferroelectric or piezoelectric functional layer, if this is required or desired depending on the application.

Preferably, one or more AC voltages can be applied between the (first) electrode layer 11a and the (second) electrode layer 12 (counter electrode) and/or between the (first) electrode layer 11b and the (second) electrode layer 12 (counter electrode), whereby the AC voltages applied to the (first) electrode layers 11a and 11b can be in phase or out of phase relative to each other, can be controlled at the same or different frequencies and/or can also be at the same or different amplitudes. In some embodiments, several AC voltage sources can also be used for different actuator surfaces (e.g. with different frequencies for oscillations in transverse or perpendicular torsion or oscillation axes, e.g. via springs of a spring structure, e.g. with bending springs, torsion springs and/or Meander springs, e.g. for 2D Lissajous scanning movements or preferably resonant 2D Lissajous scanning movements of the mirror 111).

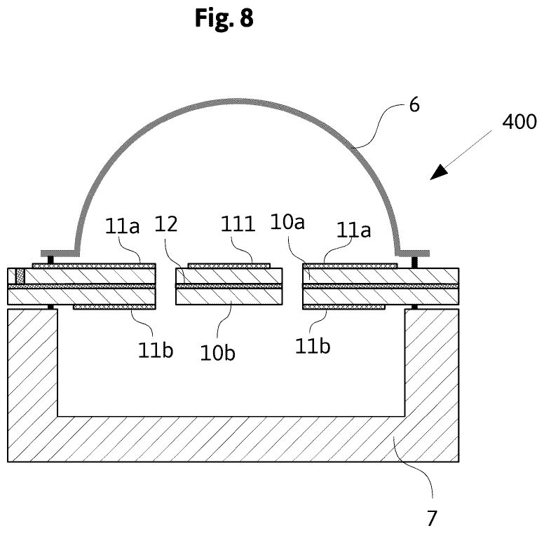

FIG. 8 shows an exemplary schematic sectional view of a MEMS apparatus 400, which exemplarily comprises the layer structure according to FIG. 7(vi). Here, too, the layered structure can be hermetically sealed from above with a translucent cover element 6 (e.g. a translucent dome element or a glass dome) and/or from below with a base element or base body element 7 in a vacuum atmosphere (e.g. vacuum encapsulation).

In further embodiments, differently shaped cover elements or 3D-shaped cover elements are also possible (e.g. angular or planar, e.g. also an inclined window or a planar window). The material of the cover elements is preferably translucent, e.g. glass or other optically transparent materials (e.g. approx. 400-2500 nm), such as borosilicate glass (e.g. Borofloat® BF33 by SCHOTT).

Accordingly, an exemplary vacuum-packed (or vacuum-encapsulated) MEMS mirror device 400 (e.g., a MEMS mirror scanner) comprising the fabricated layered structure may be provided with piezoelectrically deflectable or controllable mirrors 111 that are exemplary configured for 1D and/or 2D scanning movements of the mirror 111 (e.g., 2D scanning movements or preferably resonant 2D scanning movements for Lissajous scans, i.e. e.g. a bi-resonant mirror 111 with two resonant axes for Lissajous scans, e.g. via springs of a spring structure, e.g. with bending springs, torsion springs and/or Meander springs).

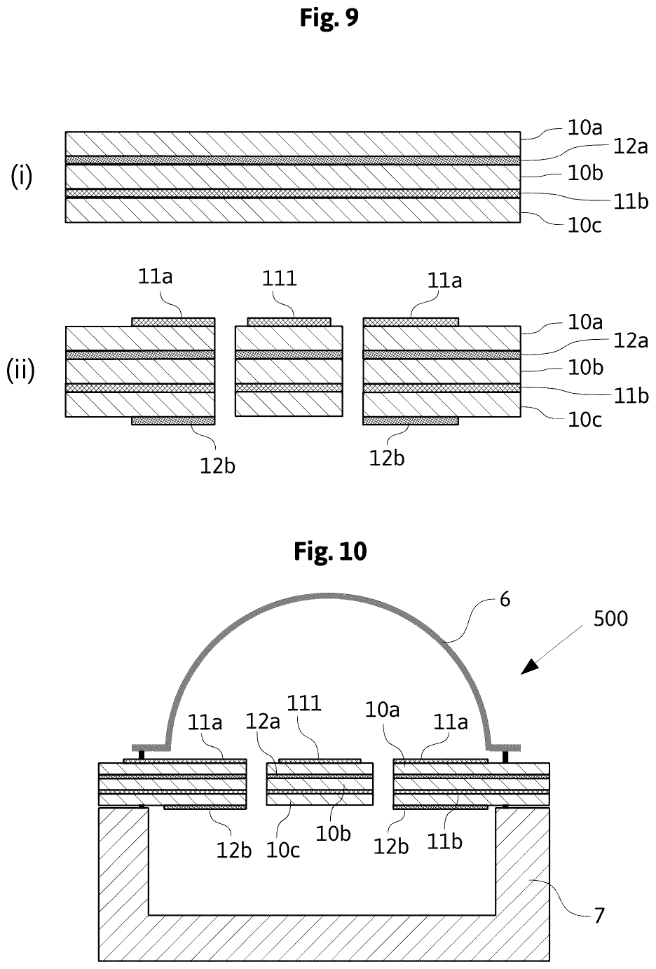

FIG. 9 shows exemplary sectional views of the layered structure during a manufacturing process according to an exemplary manufacturing sequence of a further exemplary embodiment. Here, only the exemplary starting substrate (see FIG. 9(i)) and the exemplary finished layer structure (see FIG. 9(ii)) are shown. Any intermediate structuring steps of the functional and electrode layer can be carried out in various possible ways and sequences analogous to the above exemplary embodiments.

In contrast to the above exemplary embodiments, an exemplary starting substrate according to FIG. 9(i) is provided, which exemplarily comprises three ferroelectric or piezoelectric functional layers 10a, 10b and 10c. These three ferroelectric or piezoelectric functional layers 10a, 10b and 10c (or the ferroelectric or piezoelectric layers 10a, 10b and 10c that form the functional layer) can comprise the same ferroelectric or piezoelectric material and/or also different ferroelectric or piezoelectric materials.

As an example, the starting substrate according to FIG. 9(i) can also already be provided in such a way that a respective electrode layer 11b (first electrode layer) or electrode layer 12a (second electrode layer), e.g. as metallic electrode layer(s), are arranged between respective adjacent ferroelectric or piezoelectric functional layers. As an example, the starting substrate according to FIG. 9(i) can be provided in some embodiments in such a way that the ferroelectric or piezoelectric functional layers 10a, 10b and 10c and the exemplary (first and/or second) electrode layers 11b or 12a located in between are already bonded or laminated.

On opposite outer sides (e.g. front and rear sides) of the starting substrate according to FIG. 9(i), respective electrode layers 11a (first electrode layer) and 12b (second electrode layer) are arranged exemplarily. The electrode layers 11a and 12b can, for example, either be applied to the starting substrate (e.g. by deposition processes) or can also, for example, already be provided in the starting substrate (e.g. bonded or laminated to the respective functional layer 10a/10c).

The (second) electrode layers 12a and 12b each form, exemplarily, the corresponding counter-electrodes to the respective (first) electrode layers 10a, 10b and 10c, so that, exemplarily, each ferroelectric or piezoelectric functional layer is arranged between a respective first electrode layer and a respective second electrode layer (corresponding counter-electrode). The electrode layers 12a and/or 12b can, for example, be structured analogously to the electrode layers 11a and/or 11b. In general, the electrode layers 11a and/or 12a and/or the electrode layers 11b and/or 12b need not be symmetrical.

Here, the mechanically effective structures of the MEMS apparatus can be formed in the ferroelectric or piezoelectric functional layer(s), in particular by structuring the ferroelectric or piezoelectric functional layers, 10b and 10c (and, for example, also structuring the electrode layers 12a and 11b); see, for example, FIG. 9(ii).

This includes, for example, forming or exposing the mirror support element formed from (e.g. central) regions of the ferroelectric or piezoelectric functional layers 10a, 10b and 10c (here, for example, the region under the mirror layer 111) and the retaining webs, which can be formed from the functional layers 10a, 10b and 10c and can act, for example, as a holding spring structure, and which can, for example, hold the mirror support element so that it can oscillate about one, two or more oscillation or torsion axes (e.g. about an oscillation/torsion axis or about two oscillation/torsion axes that are preferably transverse or, in particular, perpendicular to one another, e.g. via springs of the spring structure, e.g. with bending springs, torsion springs and/or Meander springs, in particular e.g. for Lissajous scanning movements or preferably resonant Lissajous scanning movements). In general, the ferroelectric or piezoelectric functional layers 10a, 10b and/or 10c do not have to be symmetrically structured.

In some exemplary embodiments, the spring structure may comprise springs, in particular preferably bending springs, Meander springs and/or torsion springs, which are preferably designed to hold the mirror support element in such a way that the mirror support element can perform an oscillating rotational movement about the respective oscillating and/or torsional axis (e.g. torsional oscillations).

The respective electrode layers 11a, 12a, 11b and/or 12b may, exemplarily, be made of metal, preferably aluminum, or comprise metal, preferably aluminum, for example either of the same metal or also of different metals.

In some preferred embodiments, the material of the metallic electrode layer 11a or mirror layer 111 can be selected depending on the desired application for the respective wavelength range, in particular with very good reflection behavior in the wavelength range of the desired application, for example aluminum or silver for visible light (e.g. essentially at wavelengths of 400-700 nm) or gold for infrared light or infrared radiation (e.g. essentially at wavelengths of 850-2000 nm).

FIG. 10shows an exemplary schematic sectional view of a MEMS apparatus 500, which exemplarily comprises the layer structure according to FIG. 9 (ii). The layered structure can be hermetically sealed from above with a translucent cover element 6 (e.g. a translucent dome element or a glass dome) and/or from below with a base element or base body element 7 under a vacuum atmosphere (e.g. vacuum encapsulation).

In some further embodiments, differently shaped cover elements or 3D-shaped cover elements are also possible (e.g. angular or planar, e.g. also an inclined window or a planar window). The material of the cover elements is preferably translucent, e.g. glass or other optically transparent materials (e.g. approx. 400-2500 nm), such as borosilicate glass (e.g. Borofloat® BF33 by SCHOTT).

Accordingly, an exemplary vacuum-packed (or vacuum-encapsulated) MEMS mirror device 500 (e.g., a MEMS mirror scanner) comprising the fabricated layered structure may be provided with piezoelectrically deflectable or controllable mirrors 111 that are exemplary configured for (preferably resonant) 1D and/or 2D scanning movements of the mirror 111 (e.g., 2D scanning movements for Lissajous scans, i.e., e.g., a bi-resonant mirror 111 with two resonant axes for Lissajous scans, e.g. via springs of a spring structure, e.g. with bending springs, torsion springs and/or Meander springs).

In operation, such layer structures described above exemplarily with one, two, three or more ferroelectric and/or piezoelectric functional layers for a MEMS apparatus or such MEMS apparatuses according to some exemplary embodiments can be set up for periodic movements or oscillations in the frequency range from about 1 Hz to the kHz range, in embodiment examples preferably for frequencies substantially less than or equal to 200 kHz and in particular preferably for frequencies substantially less than or equal to 100 kHz. This distinguishes such MEMS apparatuses from so-called oscillating quartz devices, which are set up for the frequency range in the MHz range.

In the above embodiments, there is in particular an underlying idea that, for example, instead of a silicon substrate, a substrate can be used as the starting substrate which comprises ferro- and/or piezoelectric material, and in particular comprises at least one functional layer which comprises ferro- and/or piezoelectric material. In particular, in some embodiments, the starting substrate may preferably comprise one or more ferroelectric and/or piezoelectric layers or one or more functional layers comprising ferroelectric and/or piezoelectric material.

In this way, numerous process steps can be saved in terms of costs and time, in particular because deposition processes, e.g. of a piezoelectric layer, can be avoided. In addition, the ferroelectric and/or piezoelectric substrate can form the at least one functional layer in which the movable elements of the MEMS and/or the spring structure holding them can later be formed. The at least one functional layer can preferably form both the mechanically effective layer and at the same time drive and/or detect the oscillating movements as an actuator and/or sensor.

In relation to a MEMS, “mechanically effective” here may mean in particular that the mechanically effective layer or the at least one mechanically effective functional layer (Device Layer) of the MEMS layered structure preferably forms the layer which, according to its structuring, is designed or formed to perform a one-dimensional or two-dimensional oscillatory movement, or in such a way that one or more structures or bodies which are formed in the mechanically effective layer or mechanically effective functional layer can perform a one-dimensional or two-dimensional oscillatory movement (e.g. about an oscillatory/torsional axis or about two preferably transverse or in particular perpendicular axes, e.g. via springs of a spring structure, e.g. with bending springs, torsion springs and/or Meander springs, in particular e.g. for Lissajous scanning movements or preferably resonant Lissajous scanning movements).

Preferably, the holding structure and/or spring structure for the movable structures or bodies of the mechanically effective layer or mechanically effective functional layer can also be formed in this mechanically effective layer or mechanically effective functional layer for this purpose.

Furthermore, the formation of the mechanically effective layer or mechanically effective functional layer can preferably determine the resonant frequency or resonant frequencies of the MEMS, the deflection amplitudes and/or any dynamic deformations (e.g. in a holding structure and/or spring structure formed in the mechanically effective layer or mechanically effective functional layer or the formed structures or bodies, such as the mirror support element with the mirror plate 111).

In addition, the starting substrate or the one or more functional layers in the starting substrate in the embodiments described above can be provided as a ferro- and/or piezoelectric single crystal or polycrystal and thus optimal ferro-/piezoelectric properties with optimal ferro-/piezoelectric coefficients can be provided, which is not possible in conventional deposition processes due to the process variations and growth conditions. Furthermore, compared to the prior art, in which ferro/piezoelectric layers are deposited on a silicon substrate, comparatively thicker ferro/piezoelectric layers can be provided in the starting substrate in some embodiments, so that a higher force development is advantageously made possible.

In the exemplary embodiments described above, the starting substrate comprising the at least one functional layer may comprise ferroelectric and/or piezoelectric material. In the exemplary embodiments described above, one or more functional layers of the starting substrate may comprise ferroelectric and/or piezoelectric material. Preferably, the starting substrate comprising the at least one functional layer may comprise one or more piezoelectric layers of ferro- and/or piezoelectric material, in particular one or more functional layers of ferro- and/or piezoelectric material.

In the embodiments described above, the starting substrate comprising the at least one functional layer and/or the at least one functional layer of the starting substrate may comprise a single crystal of a ferro- and/or piezoelectric material and/or consist of a single crystal of a ferro- and/or piezoelectric material.

In the embodiments described above, the starting substrate comprising the at least one functional layer and/or at least one functional layer of the starting substrate may comprise a polycrystal of a ferro- and/or piezoelectric material and/or may consist of a polycrystal of a ferro- and/or piezoelectric material.

In particular, the starting substrate is preferably not a silicon substrate and preferably the starting substrate does not comprise silicon or a functional layer comprising silicon.

In some exemplary embodiments described above, the ferro- and/or piezoelectric material may comprise aluminum nitride (AlN), aluminum scandium nitride (AlScN), lithium niobate (LiNbO3), lithium tantalate (LiTaO3), lead zirconate titanate (PZT), niobium-doped PZT (PZT-Nb) and/or quartz.

In some exemplary embodiments described above, the starting substrate comprising the at least one functional layer and/or at least one functional layer of the starting substrate may comprise a ferro- and/or piezoelectric material that is at least partially amorphous and/or consist of a ferro- and/or piezoelectric material that is at least partially amorphous. Here, the (partially) at least partially amorphous (e.g. (partially) amorphous) ferroelectric and/or piezoelectric material may comprise, for example, PVDF (polyvinylidene fluoride (CF2—CH2)n) or consist of PVDF.

In some exemplary embodiments described above with multiple functional layers in the starting substrate, the starting substrate can be provided such that the starting substrate comprises, for example, at least one functional layer comprising or consisting of a ferro- and/or piezoelectric single crystal, at least one functional layer comprising or consisting of a ferro- and/or piezoelectric polycrystal, and/or at least one functional layer comprising or consisting of an at least partially amorphous (e.g. (partially) amorphous) ferro- and/or piezoelectric material. (e.g. (partially) amorphous) ferro- and/or piezoelectric material or consists thereof.

In some exemplary embodiments described above, a layer thickness of the at least one functional layer of the starting substrate comprising ferroelectric and/or piezoelectric material may be substantially greater than or equal to 50 μm, in particular substantially greater than or equal to 100 μm, and/or substantially less than or equal to 1 mm. In particular preferred embodiments with several functional layers comprising ferroelectric and/or piezoelectric material, the layer thickness of each functional layer is each case preferably substantially greater than or equal to 50 μm, in particular preferably substantially greater than or equal to 100 μm, and/or substantially less than or equal to mm.

In some exemplary embodiments described above, in particular when structuring the at least one functional layer, a spring structure which holds the mirror support element with mirror can be formed in the at least one functional layer, in particular in some embodiments preferably in such a way that the mirror support element with mirror is held such that it can oscillate, for example about one or two axes, in particular e.g. oscillation and/or torsion axes, e.g. via springs of a spring structure, e.g. with torsion springs and/or Meander springs.

In some exemplary embodiments, the spring structure may comprise, for example, springs, in particular preferably bending springs, Meander springs and/or torsion springs, which are preferably designed to hold the mirror support element in such a way that the mirror support element can perform an oscillating rotational movement about the respective oscillating and/or torsional axis (e.g. torsional oscillations).

In some exemplary embodiments with two axes, in particular oscillating and/or torsional axes, the mirror support element with mirror and/or the spring structure is in particular preferably designed for a (preferably resonant) two-dimensional Lissajous scanning movement of the mirror support element with mirror.

Above, exemplary embodiments of layered structures with multiple layers have been described. It should be noted that such embodiments should not be understood to be limiting in the sense that no further intermediate layers can be present in further embodiments. On the contrary, in further embodiments further layers and/or intermediate layers may be provided and/or described layers may be omitted.

It should be noted that only examples or embodiments of the present disclosure and technical advantages have been described in detail above with reference to the accompanying drawings. However, the present disclosure is in no way limited or restricted to the above-described embodiments and their embodiment features or their described combinations, but further includes modifications of the embodiments, in particular those which are encompassed by modifications of the features of the described examples or by combination or partial combination of individual or several of the features of the described examples within the scope of protection of the independent claims.

### LIST OF REFERENCE SIGNS

1 Substrate layer
2 Passivation layer(s)
2b Passivation layer
3 Functional layer (Device Layer)
3a Trenches or structured areas of the functional layer
4 Piezoelectric layer
5 Electrode layer
5a Mirror
6 Cover element
7 Base element
10 Piezoelectric functional layer (Device Layer)
10a First piezoelectric functional layer
10b Second piezoelectric functional layer
10c Third piezoelectric functional layer
11 First electrode layer (top electrode)
11a First electrode layer
11b First electrode layer
111 Mirror
12 Second electrode layer (bottom electrode; counter electrode)
12a Second electrode layer (counter electrode)
12b Second electrode layer (counter electrode)
100 MEMS apparatus
200 MEMS apparatus
300 MEMS apparatus
400 MEMS apparatus
500 MEMS apparatus

1. A method of manufacturing a layered structure for a MEMS apparatus, in particular a vacuum-packed MEMS mirror device, comprising:
providing a starting substrate comprising at least one functional layer, wherein the at least one functional layer of the starting substrate comprises ferro- and/or piezoelectric material, and
structuring the at least one functional layer of the starting substrate to form one or more movable elements of the MEMS apparatus in the at least one functional layer and/or for forming a spring structure, which holds the one or more movable elements of the MEMS apparatus, in the at least one functional layer.

2. Method according to claim 1, characterized in that
the starting substrate, which comprises the at least one functional layer, consists of ferroelectric and/or piezoelectric material.

3. Method according to claim 1, characterized in that
the starting substrate, which comprises the at least one functional layer, comprises one or more piezoelectric layers of ferroelectric and/or piezoelectric material, in particular one or more functional layers made of ferroelectric and/or piezoelectric material.

4. Method according to claim 1, characterized in that
the starting substrate comprising the at least one functional layer and/or at least one functional layer of the starting substrate comprises a single crystal of a ferro- and/or piezoelectric material and/or consists of a single crystal of a ferro- and/or piezoelectric material.

5. Method according to claim 1, characterized in that
the starting substrate, which comprises the at least one functional layer, and/or at least one functional layer of the starting substrate comprises a polycrystal of a ferro- and/or piezoelectric material and/or consists of a polycrystal of a ferro- and/or piezoelectric material.

6. Method according to claim 1, characterized in that
the ferro- and/or piezoelectric material comprises aluminum nitride (AIN), aluminum scandium nitride (AlScN), lithium niobate (LiNbO3), lithium tantalate (LiTaO3), lead zirconate titanate (PZT), niobium-doped PZT (PZT-Nb) and/or quartz.

7. Method according to claim 1, characterized in that
the starting substrate, which comprises the at least one functional layer, and/or at least one functional layer of the starting substrate comprises an at least partially amorphous ferroelectric and/or piezoelectric material and/or consists of an at least partially amorphous ferroelectric and/or piezoelectric material.

8. Method according to one of the preceding claims claim 1, characterized in that
a layer thickness of the at least one functional layer of the starting substrate, which comprises ferroelectric and/or piezoelectric material, is substantially greater than or equal to 50 μm, in particular substantially greater than or equal to 100 μm, and/or substantially less than or equal to 1 mm.

9. Method according to claim 1, characterized by
applying and/or providing electrically conductive electrode layers on respective opposite sides of the at least one functional layer, and
structuring the electrode layers to form structured electrode surfaces on respective opposite sides of the at least one functional layer.

10. Method according to claim 9, characterized in that
a mirror of the MEMS apparatus is formed in the structuring of one of the electrode layers, in particular in the structuring of an outer electrode layer.

11. Method according to claim 1, characterized in that
a mirror support element is formed in the at least one functional layer during the structuring of the at least one functional layer of the starting substrate, wherein a mirror is arranged and/or formed on the mirror support element.

12. Method according to claim 11, characterized in that
during the structuring of the at least one functional layer, a spring structure, which holds the mirror support element with mirror, is formed in the at least one functional layer.

13. Method according to claim 12, characterized in that
the spring structure is designed such that the mirror support element with mirror is held so that it can oscillate about one or two axes, in particular oscillation axes and/or torsion axes, in particular preferably for a two-dimensional Lissajous scanning movement of the mirror support element with mirror.

14. Method according to claim 9, characterized in that
the conductive electrode layers for electrical contacting are formed on opposite sides of the functional layer.

15. Method according to claim 9, characterized in that
at least one second electrode layer of the conductive electrode layers is guided by through-hole plating in a region of the at least one functional layer from a second side of the at least one functional layer to a first side of the at least one functional layer, on which a first electrode layer of the conductive electrode layers is arranged.

16. Method according to claim 15, characterized in that
at least the first electrode layer and the second electrode layer are designed, by through-hole plating of the second electrode layer , to provide electrical contacting of the first and second electrode layers on the same first side of the functional layer.

17. Method according to claim 1, characterized in that
the starting substrate comprises a ferroelectric and/or piezoelectric functional layer.

18. Method according to claim 1, characterized in that
the starting substrate comprises two ferro- and/or piezoelectric functional layers with an electrode layer arranged in between.

19. Method according to claim 1, characterized in that
the starting substrate comprises three or more ferroelectric and/or piezoelectric functional layers, a respective electrode layer being arranged between adjacent ferroelectric and/or piezoelectric functional layers.

20. A layered structure produced in particular by the method according to claim 1, comprising:
at least one structured functional layer in which one or more movable elements of the MEMS apparatus and/or a spring structure holding the one or more movable elements of the MEMS apparatus are formed,
wherein the at least one functional layer comprises ferroelectric and/or piezoelectric material.

21. A MEMS apparatus, comprising:
a layered structure comprising:
at least one structured functional layer in which one or more movable elements of the MEMS apparatus and/or a spring structure holding the one or more movable elements of the MEMS apparatus are formed,
wherein the at least one functional layer comprises ferroelectric and/or piezoelectric material.
